(19) United States
(12) Patent Application Publication
(10) Pub. No.: US 2024/0322094 A1
(43) Pub. Date: Sep. 26, 2024

(54) DISPLAY PANEL, METHOD FOR MANUFACTURING THE SAME, AND DISPLAY APPARATUS

(71) Applicant: Tianma Advanced Display Technology Institute (Xiamen) Co., Ltd., Xiamen (CN)

(72) Inventor: Xiaoli LIU, Xiamen (CN)

(21) Appl. No.: 18/736,555

(22) Filed: Jun. 7, 2024

(30) Foreign Application Priority Data
Nov. 22, 2023 (CN) 202311567029.3

(51) Int. Cl. H01L 33/58; H01L 25/16

(52) U.S. Cl. CPC H01L 33/58; H01L 25/167; H01L 2933/0058

(57) ABSTRACT

Provided are a display panel, a method for manufacturing a display panel, and a display apparatus. The display panel has a display region including light-transmitting regions and non-light-transmitting regions. The display panel includes light-emitting elements located in the non-light-transmitting regions; light-transmitting parts at least partially located in the light-transmitting region; and a light-blocking layer located in the non-light-transmitting regions. A part of the light-blocking layer is located between adjacent light-emitting elements in a same non-light-transmitting region. The light-blocking layer covers a top edge of one or more of the light-emitting elements, or the light-blocking layer covers a top edge of one or more of the light-transmitting parts, or the light-blocking layer covers one or more of first metal parts adjacent to the light-transmitting regions.

### CROSS-REFERENCE TO RELATED DISCLOSURE

The present disclosure claims priority to Chinese Patent Application No. 202311567029.3, filed on Nov. 22, 2023, the content of which is incorporated herein by reference in its entirety.

### TECHNICAL FIELD

The present disclosure relates to the display field, and in particular, to a display panel, a method for manufacturing a display panel, and a display apparatus.

### BACKGROUND

In the transparent display field, a display region of a display panel includes a light-transmitting region and a non-light-transmitting region. Light-emitting elements and metal lines are arranged in the non-light-transmitting region. Since the metal lines reflect ambient light, the non-light-transmitting region is further provided with a light-blocking layer for covering the metal lines.

However, in the actual process, the light-blocking layer may deviate from its target position due to factors such as a misalignment of a lithography machine, causing that the light-blocking layer cannot completely shade the metal lines, which in turn leads to a high reflectivity of the display panel.

### SUMMARY

According to one aspect of embodiments of the present disclosure, a display panel is provided. The display panel has a display region including light-transmitting regions and non-light-transmitting regions. The display panel includes: light-emitting elements located in the non-light-transmitting regions, light-transmitting parts at least partially located in the light-transmitting region, and a light-blocking layer located in the non-light-transmitting regions. A part of the light-blocking layer is located between adjacent light-emitting elements of the light-emitting elements in a same non-light-transmitting region. The light-blocking layer covers a top edge of one or more of the light-emitting elements; the light-blocking layer covers a top edge of one or more of the light-transmitting parts; and/or, the light-blocking layer covers one or more of first metal parts and the first metal parts are adjacent to the light-transmitting regions.

According to another aspect of embodiments of the present disclosure, a method for manufacturing a display panel is provided. The display panel has a display region including light-transmitting regions and non-light-transmitting regions. The display panel includes: light-emitting elements located in the non-light-transmitting regions, light-transmitting parts at least partially located in the light-transmitting region, and a light-blocking layer located in the non-light-transmitting regions. A part of the light-blocking layer is located between adjacent light-emitting elements of the light-emitting elements in a same non-light-transmitting region. The light-blocking layer covers a top edge of one or more of the light-emitting elements; the light-blocking layer covers a top edge of one or more of the light-transmitting parts; and/or, the light-blocking layer covers one or more of first metal parts and the first metal parts are adjacent to the light-transmitting regions. The method includes: forming, on a side of a substrate, light-emitting elements located in the non-light-transmitting regions; forming light-transmitting parts at least partially located in the light-transmitting region; and forming a light-blocking layer located in the non-light-transmitting regions. A part of the light-blocking layer is located between adjacent light-emitting elements of the light-emitting elements in a same non-light-transmitting region. The light-blocking layer covers a top edge of one or more of the light-emitting elements; the light-blocking layer covers a top edge of one or more of the light-transmitting parts; and/or, the light-blocking layer covers one or more of first metal parts and the first metal parts are adjacent to the light-transmitting region.

According to yet another aspect of embodiments of the present disclosure, a display apparatus is provided. The display apparatus includes a display panel. The display panel has a display region including light-transmitting regions and non-light-transmitting regions. The display panel includes: light-emitting elements located in the non-light-transmitting regions, light-transmitting parts at least partially located in the light-transmitting region, and a light-blocking layer located in the non-light-transmitting regions. A part of the light-blocking layer is located between adjacent light-emitting elements of the light-emitting elements in a same non-light-transmitting region. The light-blocking layer covers a top edge of one or more of the light-emitting elements; the light-blocking layer covers a top edge of one or more of the light-transmitting parts; and/or, the light-blocking layer covers one or more of first metal parts and the first metal parts are adjacent to the light-transmitting regions.

### BRIEF DESCRIPTION OF DRAWINGS

In order to more clearly explain the embodiments of the present disclosure, the drawings used in the description of the embodiments will be briefly described below. The drawings in the following description are some embodiments of the present disclosure. Those skilled in the art can obtain other drawings based on these drawings.

FIG. 1 is a schematic structural diagram of a display panel according to some embodiments of the present disclosure;

FIG. 2 is a schematic structural diagram of a display panel according to some embodiments of the present disclosure;

FIG. 3 is a schematic structural diagram of a display panel according to some embodiments of the present disclosure;

FIG. 4 is a schematic structural diagram of a display panel according to some embodiments of the present disclosure;

FIG. 5 is a schematic structural diagram of a display panel according to some embodiments of the present disclosure;

FIG. 6 is a top view of a display panel according to some embodiments of the present disclosure;

FIG. 7 is a schematic diagram showing a misalignment according to some embodiments of the present disclosure;

FIG. 8 is a top view of another display panel according to some embodiments of the present disclosure;

FIG. 9 is a schematic structural diagram of a display panel according to some embodiments of the present disclosure;

FIG. 10 is a schematic structural diagram of a display panel according to some embodiments of the present disclosure;

FIG. 11 is a schematic structural diagram of a display panel according to some embodiments of the present disclosure;

FIG. 12 is a top view of another display panel according to some embodiments of the present disclosure;

FIG. 13 is a top view of another display panel according to some embodiments of the present disclosure;

FIG. 14 is a schematic structural diagram of a display panel according to some embodiments of the present disclosure;

FIG. 15 is a schematic structural diagram of a display panel according to some embodiments of the present disclosure;

FIG. 16 is a schematic structural diagram of a display panel according to some embodiments of the present disclosure;

FIG. 17 is a schematic structural diagram of a display panel according to some embodiments of the present disclosure;

FIG. 18 is a schematic structural diagram of a display panel according to some embodiments of the present disclosure;

FIG. 19 is a flowchart of a method for manufacturing a display panel according to some embodiments of the present disclosure;

FIG. 20 is a flowchart of another method for manufacturing a display panel according to some embodiments of the present disclosure; and

FIG. 21 is a schematic structural diagram of a display apparatus according to some embodiments of the present disclosure.

### DESCRIPTION OF EMBODIMENTS

In order to better understand technical solutions of the present disclosure, the embodiments of the present disclosure are described in details with reference to the drawings.

It should be clear that the described embodiments are merely part of the embodiments of the present disclosure rather than all of the embodiments. All other embodiments obtained by those skilled in the art without paying creative labor shall fall into the protection scope of the present disclosure.

The terms used in the embodiments of the present disclosure are merely for the purpose of describing specific embodiment, rather than limiting the present disclosure. The terms “a”, “an”, “the” and “said” in a singular form in the embodiment of the present disclosure and the attached claims are also intended to include plural forms thereof, unless noted otherwise.

It should be understood that the term “and/or” used in the context of the present disclosure is to describe a correlation relation of related objects, indicating that there may be three relations, e.g., A and/or B may indicate only A, both A and B, and only B. In addition, the symbol “/” in the context generally indicates that the relation between the objects in front and at the back of “/” is an “or” relationship.

In this specification, it should be understood that the terms “basically”, “approximately”, “roughly”, “about”, “generally” and “substantially” described in the claims and embodiments of this disclosure refer to a reasonable process operation range or tolerance range, which can be substantially agreed, rather than an exact value.

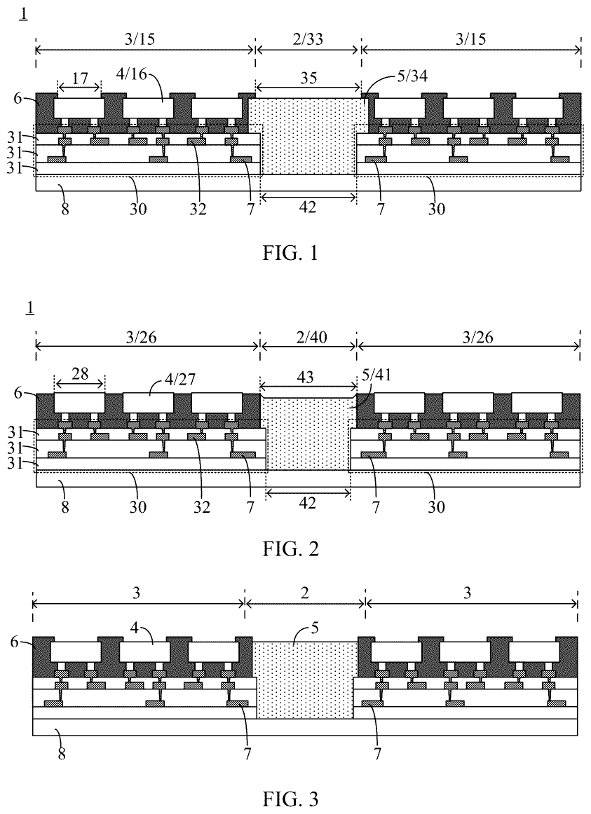

Embodiments of the present disclosure provide a display panel. The display panel provided by embodiments of the present disclosure may be a transparent display panel. FIG. 1 is a schematic structural diagram of a display panel according to some embodiments of the present disclosure. FIG. 2 is a schematic structural diagram of a display panel according to some embodiments of the present disclosure. As shown in FIG. 1 and FIG. 2, the display panel includes a display region 1, and the display region 1 includes a light-transmitting region 2 and one or more non-light-transmitting regions 3.

The display panel further includes light-emitting elements 4 which are located in the non-light-transmitting region 3. In some embodiments, the light-emitting element 4 may be a light-emitting diode (LED), for example, a Micro LED.

The display panel further includes one or more light-transmitting parts 5. The light-transmitting part 5 is at least partially located in the light-transmitting region 2 and includes a light-transmitting material. The light-transmitting part 5 fills the light-transmitting region 2 to reduce a height difference between the light-transmitting region 2 and the non-light-transmitting region 3.

The display panel further includes a light-blocking layer 6 located in the non-light-transmitting region 3. A part of the light-blocking layer 6 is located between adjacent light-emitting elements 4 in the same non-light-transmitting region 3. The light-blocking layer 6 covers a top edge of one or more light-emitting elements 4, the light-blocking layer 6 covers a top edge of one or more light-transmitting parts 5, and/or, the blocking layer 6 covers one or more first metal parts 7. The first metal part 7 is adjacent to the light-transmitting region 2.

The top edge of the light-emitting element 4 refers to an edge of a surface of the light-emitting element 4 on a side away from a substrate 8, and the top edge of the light-transmitting part 5 refers to an edge of a surface of the light-transmitting part 5 on a side away from the substrate 8. When the light-emitting element 4 is a top light-emitting element, the top edge of the light-emitting element 4 is an edge of a light-emitting surface of the light-emitting element 4.

It should be noted that a sign “,” in the expression “the light-blocking layer 6 covers a top edge of one or more light-emitting elements 4, the light-blocking layer 6 covers a top edge of one or more light-transmitting parts 5” means “or”. That is, in a structure represented by this expression, the light-blocking layer 6 covers the top edge of one or more light-emitting elements 4, in addition to this, the light-blocking layer 6 may further cover the top edge of one or more light-transmitting parts 5 or not cover the top edge of any light-transmitting part 5. In another structure represented by this expression, the light-blocking layer 6 covers the top edge of one or more light-transmitting parts 5, in addition to this, the light-blocking layer 6 may further cover the top edge of one or more light-emitting elements 4 or not cover the top edge of any light-emitting element 4.

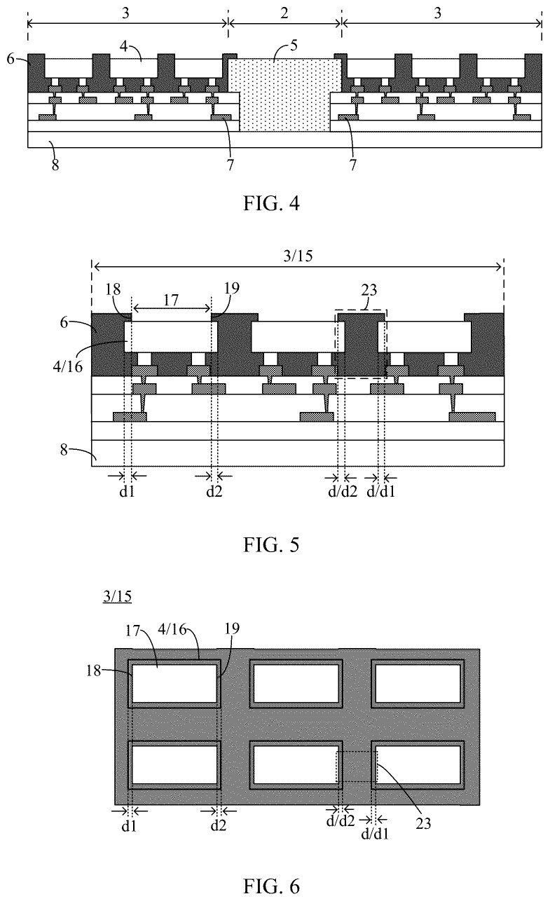

FIG. 3 is a schematic structural diagram of a display panel according to some embodiments of the present disclosure. FIG. 4 is a schematic structural diagram of a display panel according to some embodiments of the present disclosure. As shown in FIG. 1, FIG. 3, and FIG. 4, the expression “the light-blocking layer 6 covers a top edge of one or more light-emitting elements 4, the light-blocking layer 6 covers a top edge of one or more light-transmitting parts 5” includes the structure shown in FIG. 3 in which the light-blocking layer 6 covers the top edge of one or more light-emitting elements 4 but does not cover the top edge of any light-transmitting part 5, the structure shown in FIG. 4 in which the light-blocking layer 6 covers the top edge of one or more light-transmitting parts 5 but does not cover the top edge of any light-emitting element 4, and the structure shown in FIG. 1 in which the light-blocking layer 6 covers both the top edge of one or more light-emitting elements 4 and the top edge of one or more light-transmitting parts 5.

It should be noted that the term “cover” in the expression “the light-blocking layer 6 covers a top edge of one or more light-emitting elements 4, the light-blocking layer 6 covers a top edge of one or more light-transmitting parts 5, and/or, the blocking layer 6 covers one or more first metal parts 7” means that “overlap” includes “entirely overlap” and “partially overlap”. For example, the expression “the light-blocking layer 6 covers the top edge of the light-emitting element 4” means that the light-blocking layer 6 overlaps at least part of the top edge of the light-emitting element 4, the expression “the light-blocking layer 6 covers the top edge of the light-transmitting part 5” means that the light-blocking layer 6 overlaps at least part of the top edge of the light-transmitting part 5, and the expression “the light-blocking layer 6 covers the first metal part 7” means that the light-blocking layer 6 overlaps at least part of the first metal part 7.

In the display panel provided by embodiments of the present disclosure, when the light-blocking layer 6 covers the top edge of the light-emitting element 4, the light-blocking layer 6 and at least one side of the light-emitting element 4 are in close contact. On the one hand, the light-blocking layer 6 shields a metal part in a region around at least this part of the light-emitting element 4, avoiding light reflection by this metal part and reducing the reflectivity of the display panel. On the other part, there is no gap or hole between the light-blocking layer 6 and the at least one side of the light-emitting element 4, improving the reliability of the subsequent encapsulation. Similarly, when the light-blocking layer 6 covers the top edge of the light-transmitting part 5, the light-blocking layer 6 shields at least part metal part adjacent to the light-transmitting part 5, and there is no gap or hole in the region around at least part of the light-transmitting part 5.

When the light-blocking layer 6 covers the first metal part 7 adjacent to the light-transmitting region 2, a light-blocking boundary of the light-blocking layer 6 for defining the light-transmitting region 2 overlaps the first metal part 7 or extends out to form the first metal part 7. In this regard, the ambient light obliquely incident on the first metal part 7 via the light-transmitting region 2 is reduced, the light reflection of the first metal part 7 is further reduced, the blocking effect to the light reflected by the first metal part 7 is improved to a greater extent, and the reflectivity of the display panel is effectively reduced.

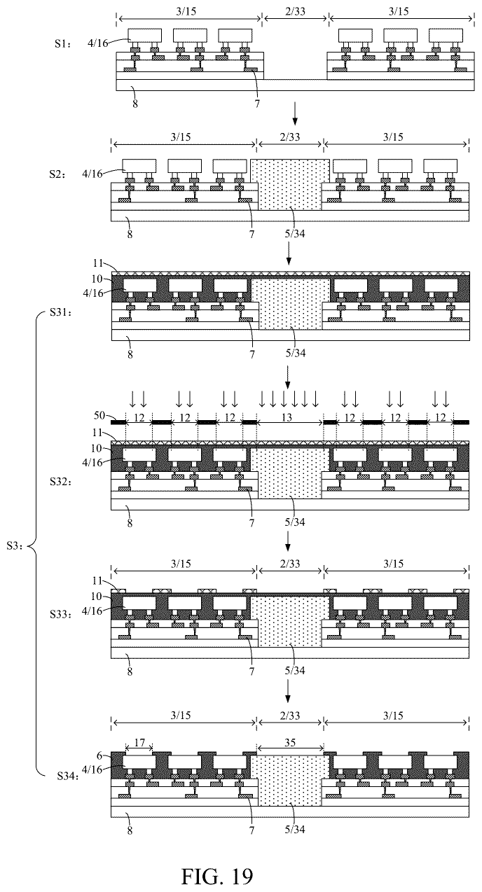

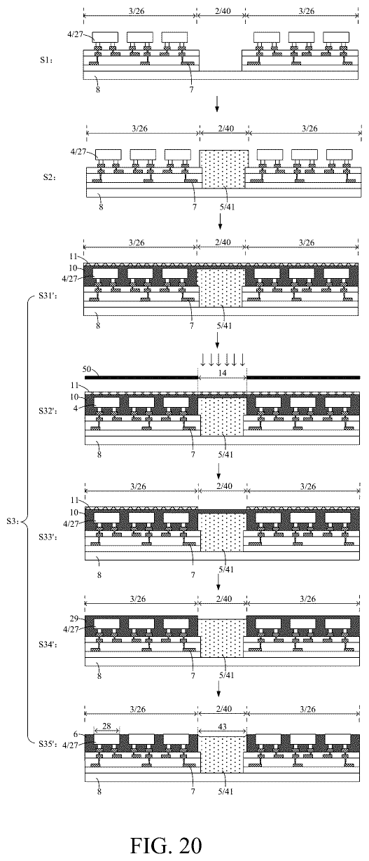

It should be noted that the light-blocking boundary of the light-blocking layer 6 is formed in the manufacturing process of the light-blocking layer 6 based on an exposure region. As shown in FIG. 19 and FIG. 20, in the manufacturing process of the light-blocking layer 6, referring to step S3, photoresist 11 is formed on a light-blocking material 10 (a positive photoresist is used as an example for description), the photoresist 11 is exposed and developed, the photoresist 11 in the exposure region is removed, and then the light-blocking material 10 not covered by the photoresist 11 is etched by an etchant. In this way, each light-blocking boundary is formed in the light-blocking layer 6.

The overlapping between the light-blocking layer 6 and the top edge of the light-emitting element 4 is formed as follows. In some embodiments of the present disclosure, as shown in FIG. 19, at least one exposure boundary of a first exposure region 12 is arranged within an orthogonal projection of the light-emitting element 4 so that there is a margin between the top edge of the light-emitting element 4 and the at least one exposure boundary. In this way, even if a mask 50 is in misalignment due to the alignment precision of the lithography machine in the manufacturing process, and/or, the light-emitting element 4 is in misalignment due to the alignment precision in the mass transfer process, the finally formed light-blocking layer 6 can cover the top edge of the light-emitting element 4. Similarly, the overlapping between the light-blocking layer 6 and the top edge of the light-transmitting part 5 is formed as follows. In some embodiments, as shown in FIG. 19, at least one exposure boundary of a second exposure region 13 is arranged within an orthogonal projection of the light-transmitting part 5 so that there is a margin between the top edge of the light-transmitting part 5 and the at least one exposure boundary. In this way, no matter whether the position of the light-transmitting part 5 or the position of the mask 50 is in misalignment, the finally formed light-blocking layer 6 can cover the top edge of the light-transmitting part 5. Similarly, the light-blocking layer 6 is formed to cover the first metal part 7 in the following method. In some embodiments, as shown in FIG. 20, at least one exposure boundary of a third exposure region 14 is arranged on a side of the first metal part 7 adjacent to the light-transmitting region 2. In this way, no matter whether the position of the first metal part 7 or the position of the mask 50 is in misalignment, the finally formed light-blocking layer 6 can cover the first metal part 7.

In addition, it should be noted that based on the design of the first exposure region 12, when at least one exposure boundary of the first exposure region 12 is arranged within an orthogonal projection of the light-emitting element 4, no matter whether the mask 50 and/or the light-emitting element 4 is in misalignment, a risk that the first exposure region 12 overlaps with a region around the light-emitting element 4 and the photoresist 11 around the light-emitting element 4 is exposed is reduced. In this way, the photoresist 11 around at least one side of the light-emitting element 4 is prevented from being dissolved by the developer solution in the developing process. In the subsequent process of etching the light-blocking material 10 by the etchant, on the at least one side of the light-emitting element 4, the etchant only etches the light-blocking material 10 on the top of the light-emitting element 4 and does not etch the light-blocking material 10 around the light-emitting element 4 and does not flow to the bottom of the light-emitting element 4 and etch the light-blocking material 10 at the bottom. In this way, a gap or residual air is prevented from existing at the bottom of the light-emitting element 4, the light-emitting element 4 is prevented from being pulled up by heated and expanded air at the bottom when the light-emitting element 4 emits light and generates heat, and the stability and reliability of the light-emitting element 4 are improved.

FIG. 5 is a schematic structural diagram of a display panel according to some embodiments of the present disclosure. FIG. 6 is a top view of a display panel according to some embodiments of the present disclosure. For conciseness and clearness, FIG. 6 only shows the part of the light-blocking layer 6 on the top of the light-emitting element 4 and the part of the light-blocking layer 6 between the light-emitting elements 4, and does not show the part of the light-blocking layer 6 at the bottom of the light-emitting elements 4. In some embodiments, as shown in FIG. 1, FIG. 5, and FIG. 6, the non-light-transmitting regions 3 include a first non-light-transmitting region 15, the light-emitting elements 4 include a first light-emitting element 16 located in the first non-light-transmitting region 15, and the light-blocking layer 6 includes a first aperture 17 located in the first non-light-transmitting region 15. The first aperture 17 overlaps with the first light-emitting element 16. The first aperture 17 includes a first edge 18 and a second edge 19 opposite to the first edge 18. In a direction perpendicular to a plane of the display panel, the first edge 18 and the second edge 19 are both located in an orthogonal projection of the first light-emitting element 16. That is, along the arranging direction of the first edge 18 and the second edge 19, a size of the first aperture 17 is smaller than a size of the first light-emitting element 16.

In this structure, the light-blocking layer 6 is in close and gapless contact with at least two opposite edges of the first light-emitting element 16, so the light-blocking layer 6 can completely shield the metal parts in the peripheral regions of the at least two opposite edges of the first light-emitting element 16, thereby further improving the light reflection phenomenon.

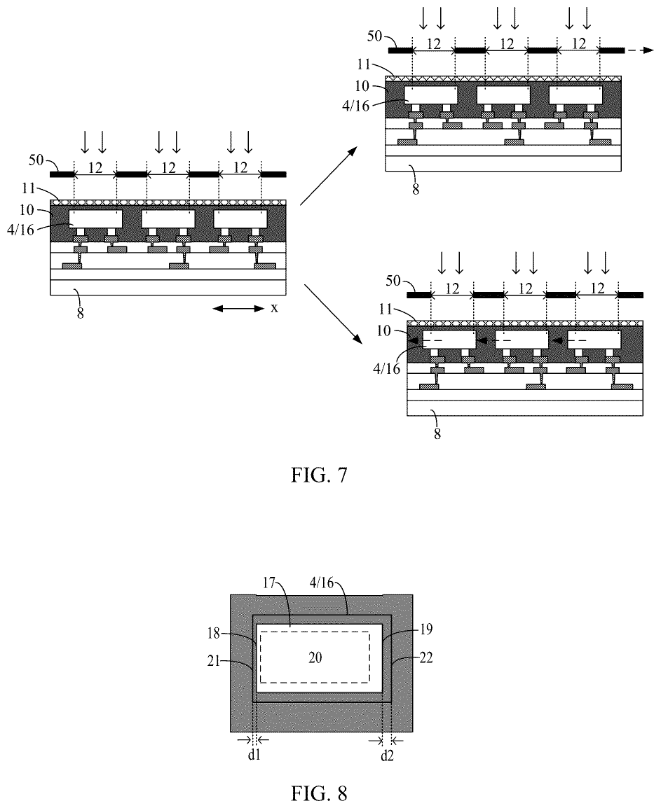

FIG. 7 is a schematic diagram showing a misalignment according to some embodiments of the present disclosure. In some embodiments, as shown in FIG. 7, when designing the first exposure region 12 corresponding to the first aperture 17, at least two opposite exposure boundaries of the first exposure region 12 are arranged in the orthogonal projection of the first light-emitting element 16. Therefore, margins in the first direction x (the arranging direction of the first edge 18 and the second edge 19) are provided for misalignment of the first light-emitting element 16 and the mask 50. Even if the first light-emitting element 16 and the mask 50 are misalignment in the first direction x, the risk that the first exposure region 12 overlaps with the periphery of the first light-emitting element 16 is reduced, and it is better avoided that the light-blocking material 10 at the bottom of the light-emitting element 4 is etched and a gap is formed at the bottom of the light-emitting element 4.

Furthermore, as shown in FIG. 5 and FIG. 6, in the direction perpendicular to the plane of the display panel, a distance d1 between the first edge 18 and the top edge of the first light-emitting element 16 adjacent to the first edge 18 is smaller than or equal to 5 μm, and a distance d2 between the second edge 19 and the top edge of the first light-emitting element 16 adjacent to the second edge 19 is smaller than or equal to 5 μm.

When designing the first exposure region 12, the two exposure boundaries of the first exposure region 12 corresponding to the first edge 18 and the second edge 19 and the top edges of the first light-emitting element 16 satisfy: no matter whether the first light-emitting element 16 and/or the mask 50 are misalignment in the first direction x, the first edge 18 and the second edge 19 of the first aperture 17 formed in the light-blocking layer 6 each have a maximum distance of 5 μm with respect to the adjacent top edge in the first light-emitting element 16. In this way, with the light-blocking layer 6 being in close and gapless contact with at least two opposite edges of the first light-emitting element 16, it is avoided that the light-blocking layer 6 shields the top surface of the first light-emitting element 16 too much and affects the brightness of the exiting light of the first light-emitting element 16, so that the display panel has a low reflectivity and a better display effect.

FIG. 8 is a top view of another display panel according to some embodiments of the present disclosure. In some embodiments, as shown in FIG. 8, in the direction perpendicular to the plane of the display panel, the distance between the first edge 18 and the top edge of the first light-emitting element 16 adjacent to the first edge 18 is the first distance d1, the distance between the second edge 19 and the top edge of the first light-emitting element 16 adjacent to the second edge 19 is the second distance d2, and the first distance d1 is smaller than the second distance d2.

In an embodiment, when designing the first exposure region 11, the distance between the exposure boundary of the first exposure region 11 corresponding to the first edge 18 and the top edge of the light-emitting element 4 is different from the distance between the exposure boundary of the first exposure region 11 corresponding to the second edge 19 and the top edge of the light-emitting element 4. Accordingly, the distance between the first edge 18 of the formed first aperture 17 and the top edge of the first light-emitting element 16 is different from the distance between the second edge 19 of the formed first aperture 17 and the top edge of the first light-emitting element 16. Alternatively, in another embodiment, when designing the first exposure region 11, the distance between the exposure boundary of the first exposure region 11 corresponding to the first edge 18 and the top edge of the light-emitting element 4 is equal to the distance between the exposure boundary of the first exposure region 11 corresponding to the second edge 19 and the top edge of the light-emitting element 4. Accordingly, the distance between the first edge 18 of the formed first aperture 17 and the top edge of the first light-emitting element 16 is equal to the distance between the second edge 19 of the formed first aperture 17 and the top edge of the first light-emitting element 16.

In some embodiments, as shown in FIG. 8, the first light-emitting element 16 includes a light-emitting region 20, and the light-emitting region 20 is arranged at a side adjacent to the first edge 18 of the first light-emitting element 16. In other words, the first light-emitting element 16 includes a first top edge 21 and a second top edge 22 opposite to the first top edge 21, the first top edge 21 is adjacent to the first edge 18, and the second top edge 22 is adjacent to the second edge 19. A distance between the light-emitting region 20 and the first top edge 21 is smaller than a distance between the light-emitting region 20 and the second top edge 22.

In some embodiments, when designing the first exposure region 11, the distance between the exposure boundary of the first exposure region 11 corresponding to the first edge 18 and the top edge of the light-emitting element 4 is arranged to be smaller, so that the distance between the first edge 18 of the formed first aperture 17 and the top edge of the first light-emitting element 16 adjacent to the first edge 18 is more likely to be smaller, thereby more likely preventing the light-blocking layer 6 from shielding the light-emitting region 20.

In some embodiments, as shown in FIG. 5 and FIG. 6, the non-light-transmitting regions 3 include a first non-light-transmitting region 15, and the light-emitting elements 4 include a first light-emitting element 16 located in the first non-light-transmitting region 15. The light-blocking layer 6 includes a first aperture 17 located in the first non-light-transmitting region 15. In a direction perpendicular to the plane of the display panel, the first aperture 17 is within an orthogonal projection of the first light-emitting element 16, so the light-blocking layer 6 can entirely cover the top edge of the first light-emitting element 16. In this way, the light-blocking layer 6 is in close contact with every side of the first light-emitting element 16, thereby better reducing light reflection and improving the stability of the first light-emitting element 16.

In some embodiments, as shown in FIG. 5 and FIG. 6, the non-light-transmitting regions 3 include first non-light-transmitting regions 15, and the light-emitting elements 4 include first light-emitting elements 16 located in the first non-light-transmitting regions 15. The light-blocking layer 6 includes a first light-blocking part 23 located in the first non-light-transmitting region 15. A portion of the first light-blocking part 23 is located between two adjacent first light-emitting elements 16, and the first light-blocking part 23 further covers top edges of two first light-emitting elements 16 adjacent to the first light-blocking part 23.

With such arrangement, the first light-blocking part 23 in close and gapless contact with sidewalls of two first light-emitting elements 16 adjacent to the first light-blocking part 23, and the first light-blocking part 23 entirely covers the metal part between the two first light-emitting elements 16, thereby reducing the reflectivity. In addition, in the lithography and etching process, it is avoided that the etchant between two adjacent first light-emitting elements 16 flows to the bottom of the first light-emitting element 16 and causes a gap at the bottom of the first light-emitting element 16.

Furthermore, as shown in FIG. 5 and FIG. 6, in the direction perpendicular to the plane of the display panel, a distance d between an edge of the light-blocking part 23 and the top edge, adjacent to the light-blocking part 23, of the first light-emitting element 16 is smaller than or equal to 5 μm. This structure may be obtained by adjusting the distance between the top edge of the first light-emitting element 16 and the exposure boundary of the first exposure region 12 corresponding to the first edge 18 and the distance between the top edge of the first light-emitting element 16 and the exposure boundary of the first exposure region 12 corresponding to the second edge 19. In this way, it is avoided that the light-blocking layer 6 shields the top surface of the first light-emitting element 16 too much and affects the brightness of the exiting light of the first light-emitting element 16.

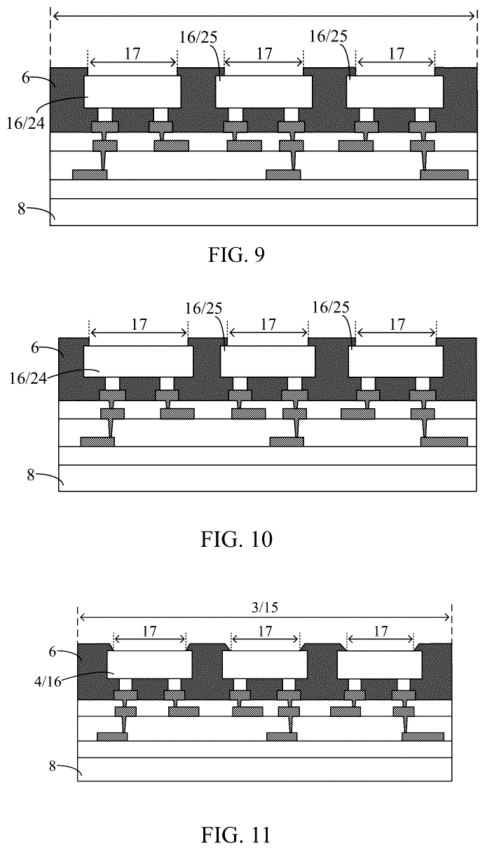

FIG. 9 is a schematic structural diagram of a display panel according to some embodiments of the present disclosure. In some embodiments, as shown in FIG. 9, the non-light-transmitting regions 3 include first non-light-transmitting regions 15, and the light-emitting elements 4 include first light-emitting elements 16 located in the first non-light-transmitting regions 15. The light-blocking layer 6 includes first apertures 17 located in the first non-light-transmitting regions 15. The first aperture 17 overlaps with the first light-emitting element 16. The first light-emitting elements 16 include a first light-emitting sub-element 24 and a second light-emitting sub-element 25 that emit light of different colors. An area of the first aperture 17 overlapping with the first light-emitting sub-element 24 is greater than an area of the first aperture 17 overlapping with the second light-emitting sub-element 25.

In some embodiments of the present disclosure, the first light-emitting elements 16 of different light-emitting colors are configured to correspond to first apertures 17 having different areas, which can meet the light-emitting requirements of the first light-emitting elements 16 of different light-emitting colors. For example, the first aperture 17 corresponding to the first light-emitting element 16 of a low emission efficiency has a larger area, thereby improving the display effect of this first light-emitting element 16.

FIG. 10 is a schematic structural diagram of a display panel according to some embodiments of the present disclosure. In some embodiments, as shown in FIG. 10, in the direction perpendicular to the plane of the display panel, an area of an orthogonal projection of the first light-emitting sub-element 24 is greater than an area of an orthogonal projection of the second light-emitting sub-element 25.

Since the first aperture 17 corresponding to the first light-emitting sub-element 24 has a larger area, when the first light-emitting sub-element 16 and/or the mask 50 is out of the target position, the light-blocking layer 6 may cover the top edge of the first light-emitting sub-element 24 as much as possible by increasing the area of the orthogonal projection of the first light-emitting sub-element 24. In other words, with ensuring that the actually formed light-blocking layer 6 can cover the top edge of the first light-emitting sub-element 24, the first aperture 17 corresponding to the first light-emitting sub-element 24 is configured to have a larger area by further increasing the area of the orthogonal projection of the first light-emitting sub-element 24, thereby further reducing the shielding of the light-blocking layer 6 on the first light-emitting sub-element 24.

A red light-emitting element 4 has a lower emission efficiency than a green light-emitting element 4 and a blue light-emitting element 4. In some embodiments of the present disclosure, the first light-emitting sub-element 24 emits red light, so the display panel has enough red light brightness. Correspondingly, the second light-emitting sub-element 25 emits blue light or green light.

FIG. 11 is a schematic structural diagram of a display panel according to some embodiments of the present disclosure. In some embodiments, as shown in FIG. 11, the non-light-transmitting regions 3 include first non-light-transmitting regions 15, and the light-emitting elements 4 include first light-emitting elements 16 located in the first non-light-transmitting regions 15. The light-blocking layer 6 includes first apertures 17 located in the first non-light-transmitting regions 15. The first aperture 17 overlaps with the first light-emitting element 16. In a direction pointing the substrate 8, at least one first aperture 17 each includes a sidewall inclining towards the interior of the first aperture 17, which allows more large-angle light to exit. In addition, when a layer such as an encapsulation layer is subsequently formed on the light-blocking layer 6, the material of this layer can more sufficiently fill the bottom of the first aperture 17, so that the material of this layer is completely in contact with the sidewall of the first aperture 17.

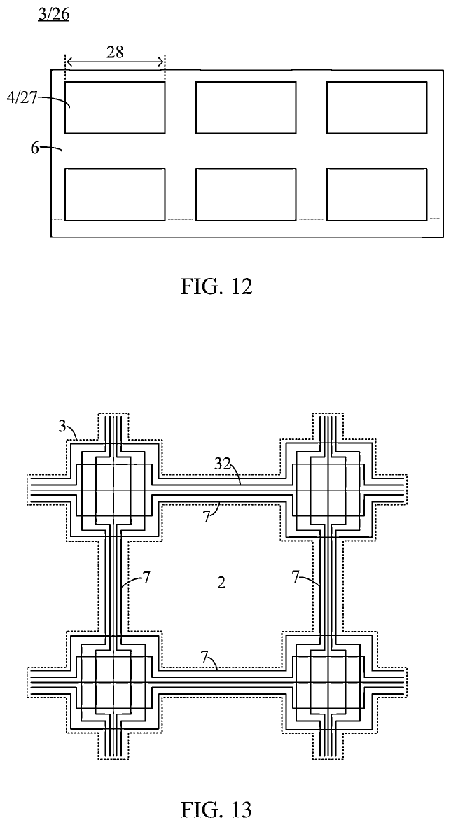

FIG. 12 is a top view of another display panel according to some embodiments of the present disclosure. In some embodiments, as shown in FIG. 2 and FIG. 12, the non-light-transmitting regions 3 include second non-light-transmitting regions 26, and the light-emitting elements 4 include second light-emitting elements 27 located in the second non-light-transmitting regions 26. The light-blocking layer 6 includes second apertures 28 located in the second non-light-transmitting regions 26. The second aperture 28 exposes a top surface of the second light-emitting element 27. The top surface of the second light-emitting element 27 is a surface of the second light-emitting element 27 on a side away from the substrate 8. A distance between the substrate 8 and a surface, on the side away from the substrate 8, of the light-blocking layer 6 in the second non-light-transmitting region 26 is not greater than a distance between the substrate 8 and the surface of the second light-emitting element 27 on the side away from the substrate 8.

Such light-blocking layer 6 can expose the entire top surface of the second light-emitting element 27 and do not block light emitted from the second light-emitting element 27, thereby achieving a better display effect.

In addition, in some embodiments of the present disclosure, the second aperture 28 may be formed in the light-blocking layer 6 by a non-lithography process. In some embodiments, as shown in FIG. 20, please refer to step S34′ and step S35′. A light-blocking part 29 to be processed is formed firstly, and the light-blocking part 29 to be processed is located in the second non-light-transmitting region 26 and covers the second light-emitting element 27. Next, the light-blocking part 29 to be processed is thinned by an ashing process to form the second aperture 28 exposing the top surface of the second light-emitting element 27. This method has the following advantages. It does not need to consider the misalignment of the second light-emitting element 27. The problem of the misalignment of the second aperture 28 due to the misalignment of the lithography machine no longer exists. It is better ensured that the light-blocking layer 6 is in close and gapless contact with all sidewalls of the second light-emitting element 27, the light reflection problem is better improved, and a gap is prevented from forming at the bottom of the second light-emitting element 27 due to the etchant flowing into the bottom of the second light-emitting element 27.

If the light-blocking layer 6 is thinned too much, the light-blocking effect is reduced. In order to avoid this, the surface, on the side away from the substrate 8, of the light-blocking layer 6 in the second non-light-transmitting region 26 is flush with the surface of the second light-emitting element 27 on the side away from the substrate 8.

In some embodiments, as shown in FIG. 1 and FIG. 2, the display panel further includes a substrate 8 and an array layer 30. The light-emitting elements 4 and the light-blocking layer 6 are located on a side of the array layer 30 away from the substrate 8. The first metal part 7 is located in the array layer 30. FIG. 13 is a top view of another display panel according to some embodiments of the present disclosure. As shown in FIG. 13, the first metal part 7 is a metal wire, and a portion of the first metal part 7 adjacent to the light-transmitting region 2 extends along an edge of the light-transmitting region 2. Since the metal wire has a larger light reflection ability, the first metal part 7 is configured to be a metal wire structure. When the light-blocking layer 6 covers the first metal part 7, the overall light reflection effect of the display panel is better reduced.

In addition, as shown in FIG. 1, FIG. 2 and FIG. 13, the array layer 30 further includes a second metal part 32. The second metal part 32 may be other metal parts in the non-light-transmitting region 3 other than the first metal part 7. For example, the second metal part 32 may include a metal wire, a gate, a source, and a drain of a transistor, and a plate of a capacitor.

In some embodiments, as shown in FIG. 1, the light-transmitting regions 2 include a first light-transmitting region 33, and the light-transmitting parts 5 include a first light-transmitting part 34. A part of the first light-transmitting part 34 is located in the first light-transmitting region 33, and the first light-transmitting part 34 covers the first metal part 7 adjacent to the first light-transmitting region 33. The light-blocking layer 6 also covers the top edge of the first light-transmitting part 34. That is, in this structure, a part of the first light-transmitting part 34 is located in the non-light-transmitting region 3, and both the first light-transmitting part 34 and the light-blocking layer 6 cover the first metal part 7 adjacent to the first light-transmitting region 33.

In this arrangement, the first light-transmitting part 34 covering the first metal part 7 is formed firstly, and then the light-blocking layer 6 is formed with a part located on the first light-transmitting part 34. In this way, the light-blocking layer 6 can cover the first metal part 7 to avoid the light reflection of the first metal part 7. In addition, with the thin light-blocking layer 6 on the first light-transmitting part 34, the light transmittance progressively changes in the direction from the first light-transmitting region 33 to the adjacent non-light-transmitting region 3, and the light blocking degree in the peripheral region of the first metal part 7 is weakened, thereby improving the light transmittance at the edge of the light-transmitting region 2.

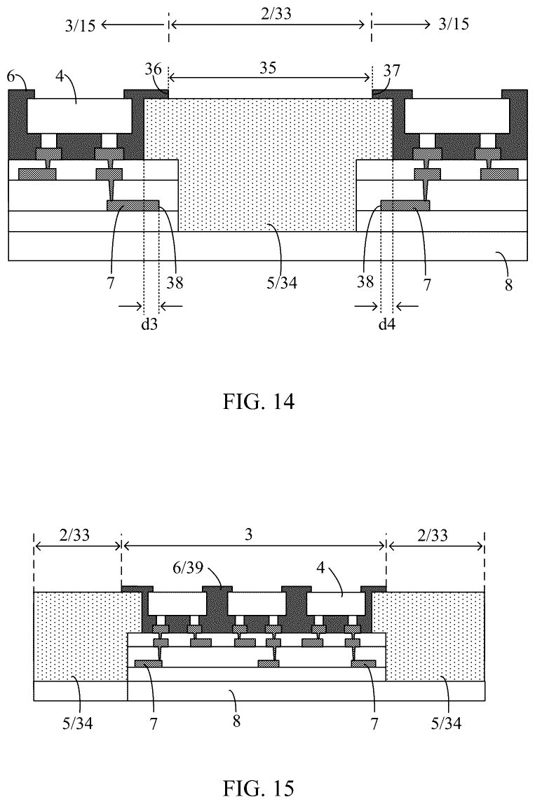

FIG. 14 is a schematic structural diagram of a display panel according to some embodiments of the present disclosure. In some embodiments, as shown in FIG. 14, the light-blocking layer 6 includes a third aperture 35 for defining the first light-transmitting region 33. The third aperture 35 includes a third edge 36 and a fourth edge 37 opposite to the third edge 36. In the direction perpendicular to the plane of the display panel, the third edge 36 and the fourth edge 37 are both located in the orthogonal projection of the first light-transmitting part 34.

In this structure, the light-blocking layer 6 is in close and gapless contact with at least two opposite edges of the first light-transmitting part 34, and can entirely shield the metal parts in peripheral regions of at least two opposite edges of the first light-transmitting part 34.

Moreover, with combining the above analysis of the second exposure region 13, as shown in FIG. 19, in some embodiments, when designing the second exposure region 13 corresponding to the third aperture 35, at least two opposite exposure boundaries of the second exposure region 13 are all located in the orthogonal projection of the first light-transmitting part 34. In this way, margins of the first light-transmitting part 34 and the mask 50 in arranging direction of the third edge 36 and the fourth edge 37 are provided for misalignment. No matter whether the first light-transmitting part 34 and the mask 50 are misalignment, there is no gap at the periphery of at least two opposite sides of the first light-transmitting part 34.

In some embodiments, as shown in FIG. 14, the first metal part 7 includes a first metal edge 38 adjacent to the light-transmitting region 2. In the direction perpendicular to the plane of the display panel, a distance d3 between the edge of the first light-transmitting part 34 and the first metal edge 38 adjacent to the first light-transmitting part 34 is smaller than or equal to 5 μm.

The light-blocking part 5 may be formed by lithography. When designing the exposure region for forming the first light-transmitting part 34, a distance between the exposure boundary of this exposure region and the first metal edge 38 satisfy the following requirement. No matter whether the lithography mask or first metal part 7 is misalignment, the maximum value of the distance between the edge of the formed first light-transmitting part 34 and the first metal edge 38 adjacent to the first light-transmitting part 34 is 5 μm. In this way, the area of the part of the light-blocking layer 6 on the top of the first light-transmitting part 34 is not too large, ensuring the light-blocking effect of the light-blocking layer 6.

In some embodiments, as shown in FIG. 14, the first metal part 7 includes a first metal edge 38 adjacent to the light-transmitting region 2, and the light-blocking layer 6 further covers the first metal edge 38 of the first metal part 7 adjacent to the first light-transmitting region 33. That is, the light-blocking layer 6 entirely covers the first metal part 7, thereby further improving the light-blocking effect.

FIG. 15 is a schematic structural diagram of a display panel according to some embodiments of the present disclosure. In some embodiments, as shown in FIG. 15, the light-transmitting regions 2 include a first light-transmitting region 33, the light-transmitting parts 5 include first light-transmitting parts 34. A part of the first light-transmitting part 34 is located in the first light-transmitting region 33. The light-blocking layer 6 further includes a second light-blocking part 39. A part of the second light-blocking part 39 is located between two adjacent first light-transmitting parts 34. The second light-blocking part 39 further covers the top edges of two first light-transmitting parts 34 adjacent to the second light-blocking part 39. In this case, the first light-blocking part 23 is in close and gapless contact with sidewalls of two adjacent first light-transmitting parts 34, thereby further reducing the reflectivity of the display panel and improving the encapsulation effect of the display panel.

In some embodiments, as shown in FIG. 2, the light-transmitting regions 2 include a second light-transmitting region 40, and the light-transmitting parts 5 include a second light-transmitting part 41 located in the second light-transmitting region 40. The light blocking layer 6 and the second light-transmitting part 41 do not overlap with each other. The light-blocking layer 6 further covers the first metal part 7 adjacent to the second light-transmitting region 40. Such light-blocking layer 6 includes a fourth aperture 43. The fourth aperture 43 exposes the entire second light-transmitting part 41.

With such arrangement, the light-blocking layer 6 covers the entire first metal part 7 adjacent to the second light-transmitting region 40, thereby preventing the area of the light-transmitting region 2 from being further reduced due to the overlapping of the light-blocking layer 6 and the second light-transmitting part 41.

It should be noted that, as shown in FIG. 20, when the non-light-transmitting regions 3 include the second non-light-transmitting region 26 and the second aperture 28 is formed in the light-blocking layer 6 by thinning the light-blocking material 10 by the ashing process, the second light-transmitting part 41 is thinned concurrently. In this way, there is no residual light-blocking material on the second light-transmitting part 41, and there is no overlapping between the light-blocking layer 6 and the second light-transmitting part 41.

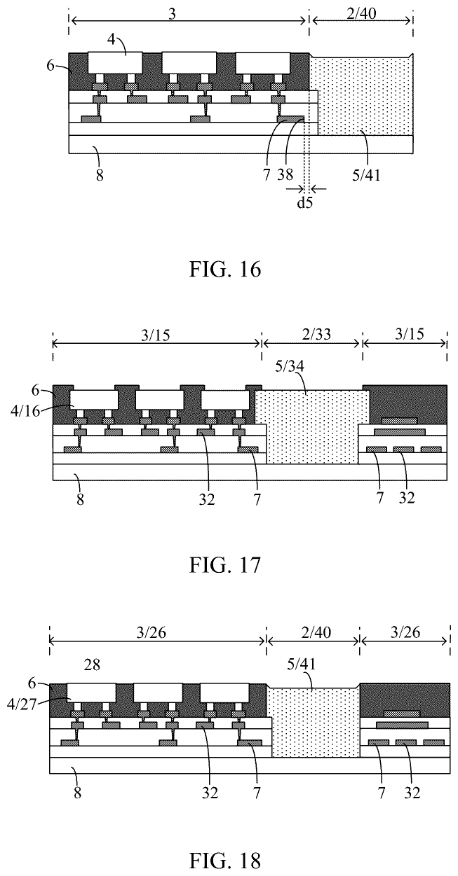

FIG. 16 is a schematic structural diagram of a display panel according to some embodiments of the present disclosure. In some embodiments, as shown in FIG. 16, the first metal part 7 includes a first metal edge 38 adjacent to the light-transmitting region 2. The light-blocking layer 6 further covers the first metal edge 38 of the first metal part 7 adjacent to the second light-transmitting region 40. In the direction perpendicular to the plane of the display panel, a distance d5 between the first metal edge 38 adjacent to the second light-transmitting region 40 and its adjacent edge of the light-blocking layer 6 is smaller than or equal to 2 μm. As a result, the blocking area of the light-blocking layer 6 is not too large, and the second light-transmitting region 40 defined by the light-blocking layer 6 has an enough area, thereby improving the overall light-transmitting effect of the display panel.

In some embodiments, as shown in FIG. 1 and FIG. 2, the display panel further includes an inorganic insulation layer 31. At least a part of the inorganic insulation layer 31 is located in the non-light-transmitting region 3. The inorganic insulation layer 31 includes a hollowed region 42. In the direction perpendicular to the plane of the display panel, the light-blocking layer 6 and the hollowed region 2 do not overlap with each other. In other words, the orthogonal projection of the light-blocking layer 6 is within the orthogonal projection of the inorganic insulation layer 31.

Compared with an organic insulation layer, the inorganic insulation layer 31 has a low light transmittance. Therefore, the inorganic insulation layer in the light-transmitting region 2 is typically hollowed out to from the hollowed region 42. In other words, the light transmittance at a position provided with the inorganic insulation layer 31 is lower than the light transmittance at a position without the inorganic insulation layer 31. Therefore, in some embodiments of the present disclosure, the light-blocking layer 6 and the hollowed region 42 of the inorganic insulation layer 31 do not overlap with each other so as to reduce the influence of the light-blocking layer 6 on the light transmittance of the display panel.

In some embodiments, the light-blocking layer 6 includes a hot-melt light-blocking material 10. Typically, the hot-melt light-blocking material 10 includes a flexible molecule chain or a small molecule. The flexible molecule chain and the small molecule has fluidity. After the light-blocking material is cured, the flexible molecule chain or the small molecule fills the gap generated due to misalignment, thereby further avoiding the gap generated between the light-blocking layer 6 and the light-emitting element 4 and between the light-blocking layer 6 and the light-blocking part.

The overall structure of the light-blocking layer 6 provided by embodiments of the present disclosure is described below with two example structures.

In one structure, as shown in FIG. 1, the display region 1 includes first non-light-transmitting regions 15 and first light-transmitting regions 33. A part of the light-blocking layer 6 is located between adjacent first light-emitting elements 16 in the same first non-light-transmitting region 15. The light-blocking layer 6 further covers the top edge of at least one first light-emitting element 16 and the top edge of at least one first light-transmitting part 34. In addition, the first light-transmitting part 34 covers the first metal part 7 so that the light-blocking layer 6 further covers at least one first light-transmitting part 34. Such light-blocking layer 6 includes the first aperture 17 and the third aperture 35.

In the other structure, as shown in FIG. 2, the display region 1 includes second non-light-transmitting regions 26 and second light-transmitting regions 40. A part of the light-blocking layer 6 is located between adjacent second light-emitting elements 27 in the same second non-light-transmitting region 26. The light-blocking layer 6 further covers the top edge of at least one first metal part 7. In addition, the light-blocking layer 6 exposes the top surface of the second light-emitting element 27, and the distance between the substrate 8 and the surface of the light-blocking layer 6 on a side away from the substrate 8 is not greater than a distance between the substrate 8 and the surface of the second light-emitting element 27 on the side away from the substrate 8. Such light-blocking layer 6 includes the second aperture 28 and the third aperture 43.

The manufacturing processes of the above two display panel structures will be described below in details with subsequent embodiments.

FIG. 17 is a schematic structural diagram of a display panel according to some embodiments of the present disclosure. It should be noted that, in some embodiments, as shown in FIG. 17, some first non-light-transmitting regions 15 are provided with the metal part (the first metal part 7 and the second metal part 32) and are not provided with the light-emitting element 4. FIG. 18 is a schematic structural diagram of a display panel according to some embodiments of the present disclosure. In some alternative embodiments, as shown in FIG. 18, some second non-light-transmitting regions 26 are provided with the metal part (the first metal part 7 and the second metal part 32) and are not provided with the light-emitting element 4.

Embodiments of the present disclosure further provide a method for manufacturing a display panel. FIG. 19 is a flowchart of a method for manufacturing a display panel according to some embodiments of the present disclosure. FIG. 20 is a flowchart of another method for manufacturing a display panel according to some embodiments of the present disclosure. As shown in FIG. 1, FIG. 2, FIG. 19 and FIG. 20, the display panel includes a display region 1, and the display region 1 includes one or more light-transmitting regions 2 and one or more non-light-transmitting regions 3. The manufacturing method includes the following steps.

In step S1, light-emitting elements 4 are formed on a side of a substrate 8, and the light-emitting elements 4 are located in the non-light-transmitting region 3.

In step S2, a light-transmitting part 5 is formed, and at least a part of the light-transmitting part 5 is located in the light-transmitting region 2.

In step S3, a light-blocking layer 6 is formed. The light-blocking layer 6 is located in the non-light-transmitting region 3. A part of the light-blocking layer 6 is located between adjacent light-emitting elements 4 within a same non-light-transmitting region 3. The light-blocking layer 6 further covers the top edge of at least one light-emitting element 4 and the top edge of at least one light-transmitting part 5, and/or, the light-blocking layer 6 further covers at least one first metal part 7 and the first metal part 7 is adjacent to the light-transmitting region 2.

The display panel manufactured by the manufacturing method provided by embodiments of the present disclosure has a low reflectivity, and reference can be made to the above description of the display panel, which is not repeated here.

In some embodiments, as shown in FIG. 1 and FIG. 19, the non-light-transmitting regions 3 include a first non-light-transmitting region 15, and the light-emitting elements 4 include a first light-emitting element 16 located in the first non-light-transmitting region 15.

Step S3 includes: a first aperture 17 is formed in the light-blocking layer 6 based on the first exposure region 12, where the first aperture 17 is located in the first non-light-transmitting region 15 and overlaps with the first light-emitting element 16. In the direction perpendicular to the plane of the substrate 8, at least one exposure boundary of the first exposure region 12 is located within the orthogonal projection of the first light-emitting element 16, so that at least one edge of the formed first aperture 17 is located within the orthogonal projection of the first light-emitting element 16.

In some embodiments, as shown in FIG. 19, step S3 includes the following steps.

In step S31, a light-blocking material 10 and a photoresist 11 are provided.

In step S32, the photoresist 11 is exposed based the first exposure region 12.

In step S33, the photoresist 11 is developed, and the photoresist 11 within the first exposure region 12 is removed.

In step S34, the light-blocking material 10 within a region not covered by the photoresist 11 is etched out, and the light-blocking layer 6 including the first aperture 17 is formed.

When at least one exposure boundary of the first exposure region 12 is within the orthogonal projection of the light-emitting element 4, even if the first light-emitting element 16 and the mask 50 are out of their target positions, this at least one exposure boundary of the first exposure region 12 overlaps with the first light-emitting element 16. On the one hand, the formed light-blocking layer 6 can cover the top edge of the first light-emitting element 16 and shields the entire metal part in a region around at least this part of the first light-emitting element 16. On the other hand, the photoresist 11 in a region around at least this part of the first light-emitting element 16 will not be exposed. Therefore, the etchant is prevented from flowing, via at least one side of the first light-emitting element 16, to the bottom of the first light-emitting element 16 and causing a gap at the bottom of the first light-emitting element 16, and the first light-emitting element 16 is prevented from being pulled up by heated and expanded air at the bottom when the first light-emitting element 16 emits light and generates heat.

Furthermore, as shown in FIG. 1, FIG. 5, FIG. 6 and FIG. 19, in a direction perpendicular to a plane of the substrate 8, at least two opposite exposure boundaries of the first exposure region 12 are located in an orthogonal projection of the first light-emitting element 16 so that at least two opposite edges of the formed first aperture 17 are located in the orthogonal projection of the first light-emitting element 16.

Such light-blocking layer 6 is in close and gapless contact with at least two opposite sides of the first light-emitting element 16. The light-blocking layer 6 can entirely shield the metal parts in peripheral regions of the at least two opposite sides of the first light-emitting element 16, thereby reducing the light reflection. In addition, at least two exposure boundaries of the first exposure region 12 are arranged within the orthogonal projection of the first light-emitting element 16, so margin in the first direction x are provided for misalignment of the first light-emitting element 16 and the mask 50. Even if the first light-emitting element 16 and the mask 50 are misalignment in the first direction x, the risk that the first exposure region 12 overlaps with the periphery of the first light-emitting element 16 is reduced, and it is better avoided that the light-blocking material 10 at the bottom of the light-emitting element 4 is etched and a gap is formed at the bottom of the light-emitting element 4.

In some embodiments, as shown in FIG. 1 and FIG. 19, the light-transmitting regions 2 include a first light-transmitting region 33.

Step S2 includes: forming a first light-transmitting part 34. A portion of the first light-transmitting part 34 is located in the first light-transmitting region 33, and the first light-transmitting part 34 covers the first metal part 7 adjacent to the first light-transmitting region 33.

Step S3 includes: forming, based on the second exposure region 13, a third aperture 35 in the light-blocking layer 6 for defining the first light-transmitting region 33. In the direction perpendicular to the plane of the substrate 8, at least one exposure boundary of the second exposure region 13 is located within the orthogonal projection of the first light-transmitting part 34 so that at least one edge of the third aperture 35 is located within the orthogonal projection of the first light-transmitting part 34.

In some embodiments, step S32 further includes exposing the photoresist 11 based on the second exposure region 13, step S33 further includes removing the photoresist 11 in the second exposure region 13, and the light-blocking layer 6 formed by step S4 further includes the third aperture 35.

In this method, the first light-transmitting part 34 is formed to cover the first metal part 7, and then a part of the light-blocking layer 6 is formed on the first light-transmitting part 34. In this way, the light-blocking layer 6 covers the first metal part 7, thereby avoiding the light reflection of the first metal part 7. In addition, with the thin light-blocking layer 6 on the first light-transmitting part 34, the light transmittance progressively changes in the direction from the first light-transmitting region 33 to the adjacent non-light-transmitting region 3, and the light blocking degree in the peripheral region of the first metal part 7 is weakened, thereby improving the light transmittance at the edge of the light-transmitting region 2.

In addition, as shown in FIG. 1 and FIG. 19, in the direction perpendicular to the plane of the substrate 8, at least two opposite exposure boundaries of the second exposure region 13 are located within the orthogonal projection of the first light-transmitting part 34 so that at least two opposite edges of the third aperture 35 are located within the orthogonal projection of the first light-transmitting part 34.

Such light-blocking layer 6 is in close and gapless contact with at least two opposite sides of the first light-transmitting part 34. The light-blocking layer 6 can entirely shield the metal parts in peripheral regions of the at least two opposite sides of the first light-transmitting part 34. In addition, at least two opposite exposure boundaries of the second exposure region 13 are all located within the orthogonal projection of the first light-transmitting part 34. In this way, margin in the arrangement direction of the third edge 13 and the fourth edge 14 are provided for misalignment of the first light-transmitting part 34 and the mask 50. No matter whether the mask 50 is misalignment, there is no gap at the periphery of at least two opposite sides of the first light-transmitting part 34.

In some embodiments, as shown in FIG. 2 and FIG. 20, the non-light-transmitting regions 3 include a second non-light-transmitting region 26, and the light-emitting elements 4 include a second light-emitting element 27 located in the second non-light-transmitting region 26.

Step S3 includes the following steps. A light-blocking part 29 to be processed is formed. The light-blocking part 29 to be processed covers the second non-light-transmitting region 26. The light-blocking part 29 to be processed is thinned so as to form the second aperture 28 in the processed light-blocking layer 6. The second aperture 28 exposes the top surface of the second light-emitting element 27. A distance between the substrate 8 and a surface of the light-blocking layer 6 in the second non-light-transmitting region 26 on a side away from the substrate 8 is not greater than a distance between the substrate 8 and a surface of the second light-emitting element 27 on the side away from the substrate 8.

In some embodiments, as shown in FIG. 20, step S3 may include the following steps.

In step S31′, a light-blocking material 10 and a photoresist 11 are provided.

In step S32′, the photoresist 11 is exposed based on a third exposure region 14.

In step S33′, the photoresist 11 is developed, and the photoresist 11 in the third exposure region 14 is removed.

In step S34′, the light-blocking material 10 in the region not covered by the photoresist 11 is etched out, and the light-blocking part 29 to be processed is formed.

In step S35′, the light-blocking part 29 to be processed is thinned by an ashing process so as to form the second aperture 28 in the processed light-blocking layer 6.

Such light-blocking layer 6 can expose the entire top surface of the second light-emitting element 27 and do not block light emitted from the second light-emitting element 27, thereby improving the display effect. In addition, in the embodiment of the present disclosure, the second aperture 28 is formed in the light-blocking layer 6 by a non-lithography method. In this method, it does not need to consider the misalignment of the second light-emitting element 27. Moreover, the problem of the misalignment of the second aperture 28 due to the misalignment of the lithography machine no longer exists. It is better ensured that the light-blocking layer 6 is in close and gapless contact with all sidewalls of the second light-emitting element 27, the light reflection problem is better improved, and the problem that the etchant flows to the bottom of the second light-emitting element 27 causing a gap at the bottom of the second light-emitting element 27 is avoided.

In some embodiments, as shown in FIG. 2 and FIG. 20, the light-transmitting regions 2 include a second light-transmitting region 40.

Step S2 includes forming a second light-transmitting part 41. The second light-transmitting part 41 is located in the second light-transmitting region 40.

Step S3 includes forming the light-blocking part 29 to be processed. The light-blocking part 29 to be processed covers the non-light-transmitting region 3 (for example, the second non-light-transmitting region 26) adjacent to the second light-transmitting region 40. The light-blocking part 29 to be processed further covers the first metal part 7 adjacent to the second light-transmitting region 40. The light-blocking part 29 to be processed and the second light-transmitting part 41 are thinned so that the processed light-blocking layer 6 and the second light-transmitting part 41 do not overlap with each other.

In some embodiments, when the light-blocking part 29 to be processed is formed by steps S31′ to S34′ and the light-blocking part 29 to be processed is thinned by the ashing method in step 35′, the second light-transmitting part 41 is thinned synchronously. In this way, there is no residual light-blocking material on the second light-transmitting part 41, and thus the light-blocking layer 6 and the second light-transmitting part 41 do not overlap with each other.

With such arrangement, the light-blocking layer 6 can entirely cover the first metal part 7 adjacent to the second light-transmitting region 40, thereby preventing the area of the light-transmitting region 2 from being further reduced due to the overlapping of the light-blocking layer 6 and the second light-transmitting part 41.

In some embodiments, the light-blocking layer 6 includes a hot-melt light-blocking material 10. Typically, the hot-melt light-blocking material 10 includes a flexible molecule chain or a small molecule. The flexible molecule chain and the small molecule has fluidity. After the light-blocking material is cured, the flexible molecule chain or the small molecule fills the gap generated due to misalignment, thereby further avoiding the gap generated between the light-blocking layer 6 and the light-emitting element 4 and between the light-blocking layer 6 and the light-blocking part.

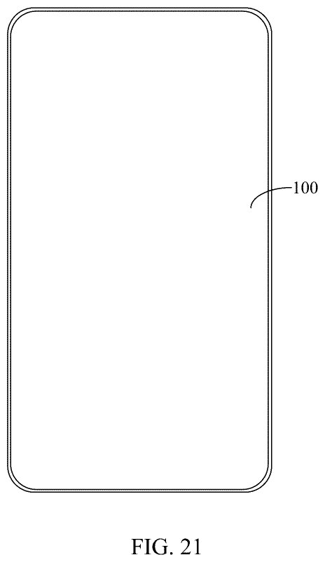

Embodiments of the present disclosure further provide a display apparatus. FIG. 21 is a schematic structural diagram of a display apparatus according to some embodiments of the present disclosure. As shown in FIG. 21, the display apparatus includes the above display panel 100. The structure of the display panel 100 has been described in the above embodiments and will not be repeated here. The display apparatus shown in FIG. 21 is merely for illustration. The display apparatus may be, for example, a display apparatus device having a display function such as a mobile phone, a tablet computer, a laptop computer, an e-reader, a television, and the like.

Embodiments described herein are only intended for ease of description and to help comprehensive understanding of this application, and are not intended to limit the scope of this application. Therefore, it should be understood that, except for the embodiments disclosed herein, all modifications and changes or forms of modifications and changes derived from the technical idea of the present application fall within the scope of the present application.

The above are merely exemplary embodiments of the present disclosure, and are not intended to limit the present disclosure. For those skilled in the art, the present disclosure may be subject to various modifications and changes. Any modification, equivalent replacement, improvement and the like within the spirit and principle of the present disclosure all fall within the protection scope of the present disclosure.

What is claimed is:

1. A display panel, comprising:
a display region comprising light-transmitting regions and non-light-transmitting regions;
light-emitting elements located in the non-light-transmitting regions;
light-transmitting parts at least partially located in the light-transmitting region; and
a light-blocking layer located in the non-light-transmitting regions,
wherein a part of the light-blocking layer is located between two adjacent ones of the light-emitting elements in a same non-light-transmitting region of the non-light-transmitting regions,
wherein the light-blocking layer covers a top edge of one or more of the light-emitting elements;
wherein the light-blocking layer covers a top edge of one or more of the light-transmitting parts; and/or
wherein the light-blocking layer covers one or more of first metal parts, the first metal parts are adjacent to the light-transmitting regions.

2. The display panel according to claim 1, wherein the non-light-transmitting regions comprise a first non-light-transmitting region, the light-emitting elements comprise a first light-emitting element located in the first non-light-transmitting region, and the light-blocking layer comprises a first aperture located in the first non-light-transmitting region,
wherein the first aperture overlaps with the first light-emitting element and comprises a first edge and a second edge opposite to the first edge, and in a direction perpendicular to a plane of the display panel, both the first edge and the second edge are located within an orthogonal projection of the first light-emitting element.

3. The display panel according to claim 2, wherein in the direction perpendicular to the plane of the display panel, a distance between the first edge and a top edge of the first light-emitting element adjacent to the first edge is smaller than or equal to 5 μm, and a distance between the second edge and a top edge of the first light-emitting element adjacent to the second edge is smaller than or equal to 5 μm.

4. The display panel according to claim 2, wherein in the direction perpendicular to the plane of the display panel, a distance between the first edge and a top edge of the first light-emitting element adjacent to the first edge is defined as a first distance, a distance between the second edge and a top edge of the first light-emitting element adjacent to the second edge is defined as a second distance, and the first distance is smaller than the second distance.

5. The display panel according to claim 4, wherein the first light-emitting element has a light-emitting region, and the light-emitting region is arranged at a side of the first light-emitting element adjacent to the first edge.

6. The display panel according to claim 1, wherein the non-light-transmitting regions comprise a first non-light-transmitting region, the light-emitting elements comprise first light-emitting elements located in the first non-light-transmitting region, and the light-blocking layer comprises a first aperture located in the first non-light-transmitting region,
wherein in a direction perpendicular to a plane of the display panel, the first aperture is located within an orthogonal projection of the first light-emitting element.

7. The display panel according to claim 1, wherein the non-light-transmitting regions comprise a first non-light-transmitting region, the light-emitting elements comprise first light-emitting elements located in the first non-light-transmitting region, and the light-blocking layer comprises a first light-blocking part located in the first non-light-transmitting region,
wherein a portion of the first light-blocking part is located between two adjacent first light-emitting elements, and the first light-blocking part further covers top edges of two first light-emitting elements adjacent to the first light-blocking part.

8. The display panel according to claim 7, wherein in a direction perpendicular to a plane of the display panel, a distance between an edge of the first light-blocking part and a top edge of the first light-emitting element adjacent to the edge of the first light-blocking part is smaller than or equal to 5 μm.

9. The display panel according to claim 1, wherein the non-light-transmitting regions comprise a first non-light-transmitting region, the light-emitting elements comprise first light-emitting elements located in the first non-light-transmitting region, and the light-blocking layer comprises first apertures located in the first non-light-transmitting region,
wherein the first apertures overlap with the first light-emitting elements, the first light-emitting elements comprises a first light-emitting sub-element and a second light-emitting sub-element that emit light in different colors, and an area of the first aperture overlapping with the first light-emitting sub-element is greater than an area of the first aperture overlapping with the second light-emitting sub-element.

10. The display panel according to claim 9, wherein in a direction perpendicular to a plane of the display panel, an area of an orthogonal projection of the first light-emitting sub-element is greater than an area of an orthogonal projection of the second light-emitting sub-element.

11. The display panel according to claim 9, wherein the first light-emitting sub-element emits red light.

12. The display panel according to claim 1, further comprising a substrate, wherein the non-light-transmitting regions comprise a first non-light-transmitting region, the light-emitting elements comprise first light-emitting elements located in the first non-light-transmitting region, and the light-blocking layer comprises first apertures located in the first non-light-transmitting region,
wherein the first apertures overlap with the first light-emitting elements, and a sidewall of at least one of the first apertures inclines inward with respect to a direction from the top of the light-emitting elements to the substrate.

13. The display panel according to claim 1, further comprising a substrate, wherein the non-light-transmitting regions comprise a second non-light-transmitting region, the light-emitting elements comprise a second light-emitting element located in the second non-light-transmitting region, and the light-blocking layer comprises a second aperture located in the second non-light-transmitting region,
wherein the second aperture exposes a top surface of the second light-emitting element, and a distance between the substrate and a surface, on a side away from the substrate, of the light-blocking layer in the second non-light-transmitting region is not greater than a distance between the substrate and a surface, on a side away from the substrate, of the second light-emitting element.

14. The display panel according to claim 13, wherein the surface, on the side away from the substrate, of the light-blocking layer in the second non-light-transmitting region is flush with the surface, on a side away from the substrate, of the second light-emitting element.

15. The display panel according to claim 1, further comprising a substrate and an array layer, wherein the light-emitting elements and the light-blocking layer are located on a side of the array layer away from the substrate,
the first metal parts are located in the array layer, the metal parts are metal wires, and a portion of the first metal parts that is adjacent to the light-transmitting region extends along an edge of the light-transmitting region.

16. The display panel according to claim 1, wherein the light-transmitting regions comprise a first light-transmitting region, the light-transmitting parts comprise a first light-transmitting part, a portion of the first light-transmitting part is located in the first light-transmitting region, the first light-transmitting part covers the first metal part adjacent to the first light-transmitting region, and the light-blocking layer covers a top edge of the first light-transmitting part.

17. The display panel according to claim 16, wherein the light-blocking layer comprises a third aperture for defining the first light-transmitting region, the third aperture comprises a third edge and a fourth edge opposite to the third edge, and in a direction perpendicular to a plane of the display panel, both the third edge and the fourth edge are within an orthogonal projection of the first light-transmitting part.

18. The display panel according to claim 16, wherein one of the first metal parts comprises a first metal edge adjacent to the light-transmitting region, and in a direction perpendicular to a plane of the display panel, a distance between an edge of the first light-transmitting part and its adjacent first metal edge is smaller than or equal to 5 μm.

19. The display panel according to claim 16, wherein one of the first metal parts comprises a first metal edge adjacent to the light-transmitting region, and the light-blocking layer covers the first metal edge of the first metal part adjacent to the first light-transmitting region.

20. The display panel according to claim 1, wherein the light-transmitting regions comprise a first light-transmitting region, the light-transmitting parts comprise first light-transmitting parts, a portion of the first light-transmitting part is located in the first light-transmitting region, the light-blocking layer comprises a second light-blocking part, a portion of the second light-blocking part is located between two adjacent light-transmitting parts, and the second light-blocking part covers top edges of two light-transmitting parts adjacent to the second light-blocking part.

21. The display panel according to claim 1, wherein the light-transmitting regions comprise a second light-transmitting region, the light-transmitting parts comprise a second light-transmitting part located in the second light-transmitting region, the light-blocking layer does not overlap with the second light-transmitting part, and the light-blocking layer further covers the first metal part adjacent to the second light-transmitting region.

22. The display panel according to claim 21, wherein one of the first metal parts comprises a first metal edge adjacent to the light-transmitting region, and the light-blocking layer further covers the first metal edge of the first metal part adjacent to the second light-transmitting region, and
in a direction perpendicular to a plane of the display panel, a distance between the first metal edge adjacent to the second light-transmitting region and an edge of the light-blocking layer adjacent to the second light-transmitting region is smaller than or equal to 2 μm.

23. The display panel according to claim 1, further comprising an inorganic insulation layer, wherein at least a part of the inorganic insulation layer is located in the non-light-transmitting region, the inorganic insulation layer comprises a hollowed region located in the light-transmitting region, and in a direction perpendicular to a plane of the display panel, the light-blocking layer does not overlap with the hollowed region.

24. The display panel according to claim 1, wherein the light-blocking layer comprises a hot-melt light-blocking material.

25. A method for manufacturing a display panel, the display panel having a display region comprising light-transmitting regions and non-light-transmitting regions, and the method comprising:
forming, on a side of a substrate, light-emitting elements located in the non-light-transmitting regions;
forming light-transmitting parts, wherein at least a part of the light-transmitting parts is located in the light-transmitting region; and
forming a light-blocking layer in the non-light-transmitting regions, wherein a part of the light blocking layer is located between adjacent light-emitting elements of the light-emitting elements in a same non-light-transmitting region of the non-light-transmitting regions,
wherein the light-blocking layer covers a top edge of one or more of the light-emitting elements;
wherein the light-blocking layer covers a top edge of one or more of the light-transmitting parts; and/or
wherein the light-blocking layer covers one or more of first metal parts, the first metal parts are adjacent to the light-transmitting regions.

26. The method according to claim 25, wherein the non-light-transmitting regions comprise a first non-light-transmitting region, the light-emitting elements comprise a first light-emitting element located in the first non-light-transmitting region,
wherein the forming the light-blocking layer comprises: forming a first aperture in the light-blocking layer based on a first exposure region, wherein the first aperture is located in the first non-light-transmitting region and overlaps with the first light-emitting element,
wherein in a direction perpendicular to a plane of the substrate, at least exposure boundary of the first exposure region is located within an orthogonal projection of the first light-emitting element so that at least one edge of the formed first aperture is located within the orthogonal projection of the first light-emitting element.

27. The method according to claim 26, wherein in the direction perpendicular to the plane of the substrate, at least two opposite exposure boundaries of the first exposure region are located within the orthogonal projection of the first light-emitting element so that at least two opposite edges of the first aperture formed are located within the orthogonal projection of the first light-emitting element.

28. The method according to claim 25, wherein the light-transmitting regions comprise a first light-transmitting region,
the forming the light-transmitting parts comprises forming a first light-transmitting part, wherein a portion of the first light-transmitting part is located in the first light-transmitting region, and the first light-transmitting part covers the first metal part adjacent to the first light-transmitting region,
the forming the light-blocking layer comprises forming, based on a second exposure region, a third aperture in the light-blocking layer for defining the first light-transmitting region, and
in the direction perpendicular to the plane of the substrate, at least one exposure boundary of the second exposure region is located within an orthogonal projection of the first light-transmitting part so that at least one edge of the formed third aperture is located within the orthogonal projection of the first light-transmitting part.

29. The method according to claim 28, wherein in the direction perpendicular to the plane of the substrate, at least two opposite exposure boundaries of the second exposure region are located within the orthogonal projection of the first light-transmitting part so that at least two opposite edges of the formed third aperture are located within the orthogonal projection of the first light-transmitting part.

30. The method according to claim 25, wherein the non-light-transmitting regions comprise a second non-light-transmitting region, and the light-emitting elements comprise a second light-emitting element located in the second non-light-transmitting region, and
the forming the light-blocking layer comprises:
forming a light-blocking part to be processed, wherein the light-blocking part to be processed covers the second non-light-transmitting region; and
thinning the light-blocking part to be processed and forming a second aperture in the processed light-blocking layer, wherein the second aperture exposes a top surface of the second light-emitting element, and a distance between the substrate and a surface of the light-blocking layer in the second non-light-transmitting region on a side away from the substrate is not greater than a distance between the substrate and a surface of the second light-emitting element on the side away from the substrate.

31. The method according to claim 25, wherein the light-transmitting regions comprise a second light-transmitting region,
the forming the light-transmitting parts comprises forming a second light-transmitting part, wherein the second light-transmitting part is located in the second light-transmitting region, and
the forming the light-blocking layer comprises:
forming a light-blocking part to be processed, wherein the light-blocking part to be processed covers the non-light-transmitting region adjacent to the second light-transmitting region and the first metal part adjacent to the second light-transmitting region; and
thinning the light-blocking part to be processed and the second light-transmitting part so that the processed light-blocking layer does not overlap with the second light-transmitting part.

32. The method according to claim 25, wherein the light-blocking layer comprises a hot-melt light-blocking material.

33. A display apparatus, comprising a display panel, wherein the display panel comprises:
a display region comprising light-transmitting regions and non-light-transmitting regions;
light-emitting elements located in the non-light-transmitting regions;
light-transmitting parts at least partially located in the light-transmitting region; and
a light-blocking layer located in the non-light-transmitting regions,
wherein a part of the light-blocking layer is located between two adjacent ones of the light-emitting elements in a same non-light-transmitting region of the non-light-transmitting regions,
wherein the light-blocking layer covers a top edge of one or more of the light-emitting elements;
wherein the light-blocking layer covers a top edge of one or more of the light-transmitting parts; and/or
wherein the light-blocking layer covers one or more of first metal parts, the first metal parts are adjacent to the light-transmitting regions.
